(19) United States
(12) Patent Application Publication
(10) Pub. No.: US 2026/0123265 A1
(43) Pub. Date: Apr. 30, 2026

(54) DISPLAY DEVICE AND METHOD OF FABRICATING THE SAME

(71) Applicant: LG DISPL AY CO., LTD., Seoul (KR)

(72) Inventors: Seong Woo PARK, Paju-si (KR); Yong In PARK, Paju-si (KR); Seung Han PAEK, Paju-si (KR); Hyun Jin AN, Paju-si (KR); Yu Cheol YANG, Paju-si (KR)

(73) Assignee: LG DISPL AY CO., LTD., Seoul (KR)

(21) Appl. No.: 19/003,893

(22) Filed: Dec. 27, 2024

(30) Foreign Application Priority Data
Feb. 14, 2024 (KR) 10-2024-0021030
Dec. 11, 2024 (KR) 10-2024-0183790

(51) Int. Cl. H10K 71/70; H10H 29/01; H10H 29/49; H10K 59/12; H10K 59/131

(52) U.S. Cl. CPC H10K 71/70; H10H 29/012; H10H 29/49; H10K 59/1201; H10K 59/131

(57) ABSTRACT

A display device can include a substrate including a display area configured to display image and a non-display area adjacent to the display area, a pad portion disposed in the non-display area of the substrate, first, second and third side surface portions located in the non-display area adjacent to the display area of the substrate, a grinding portion located in the pad portion of the substrate, and a stepped portion located between the grinding portion and at least one of the first and second side surface portions. Also, the stepped portion can include an etched surface and a grinding surface.

### CROSS-REFERENCE TO RELATED APPLICATION

This application claims priority to and the benefit of Korean Patent Application Nos. 10-2024-0021030 and 10-2024-0183790, filed in the Republic of Korea, on Feb. 14, 2024 and Dec. 11, 2024, respectively, the entireties of all these applications are incorporated herein by reference into the present application.

### BACKGROUND

### 1. Field of the Invention

The present disclosure relates to a display device and a method of fabricating the same.

### 2. Discussion of Related Art

As the information society develops, the demand for display devices for displaying images is increasing in various forms, and recently, various display devices such as liquid crystal display devices, organic light-emitting display devices, and the like have been used.

Meanwhile, in order to check whether a display panel operates normally and lights up normally during a process of fabricating a display device, a test process (that is, referred to as an auto probe process) is performed. For this test process, test pads connected to signal lines related to driving are needed. However, adding test pads to the display panel can complicate the design and manufacturing process, and undesirably increase the size of the display panel. Also, adding test pads to the display panel can increase the risk of defects or cause an edge of the display panel to be weak or susceptible to moisture penetration which an shorten the lifespan of the display device.

### SUMMARY OF THE DISCLOSURE

The present disclosure can provide a display device which can be fabricated as a display device with a robust structure as three surfaces of a display panel are etched by a chemical etching process and cut and a test pad portion, which is the remaining one surface, is cut through a scribing process using a wheel to grind the cut portion, and a method of fabricating the same.

The technical problems of the present disclosure are not limited to the above-mentioned technical problems, and other technical problems which are not mentioned will be clearly understood by those skilled in the art from the following description.

A display device according to one embodiment of the present disclosure includes a substrate including a display area and a non-display area surrounding the display area, a pad portion disposed in the non-display area of the substrate, first, second, and third side surface portions located in the non-display area adjacent to the display area of the substrate, a grinding portion located in the pad portion, and a stepped portion located between the first and second side surface portions facing each other and the grinding portion, in which the stepped portion includes an etched surface and a grinding surface.

According to another aspect of one embodiment of the present disclosure, there is provided a display device including a substrate including a display area and a non-display area surrounding the display area, a pad portion disposed in the non-display area, first to third side surface portions located in the non-display area excluding the pad portion and a round side surface portion located in the pad portion, and a stepped portion located between the first and second side surface portions facing each other and the round side surface portion, and an etch stop layer disposed on the substrate adjacent to the first to third side surface portions and the stepped portion, and a back coating film disposed on a rear surface and an outer side surface of the substrate.

According to another aspect of one embodiment of the present disclosure, there is provided a method of fabricating a display device including disposing a plurality of display panels on a mother substrate, primarily cutting the plurality of display panels having first to fourth side surface portions and round parts to separate the plurality of display panels from the mother substrate, secondarily cutting a test pad of the separated display panel, and grinding a portion of the display panel where the test pad is cut.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a plan view of a display device according to an embodiment of the present disclosure;

FIG. 2 is a cross-sectional view of areas A1-1 to A1-5 in FIG. 1 according to an embodiment of the present disclosure;

FIG. 3 is a cross-sectional view after primary cutting is performed along a primary cutting line in FIG. 2 according to an embodiment of the present disclosure;

FIG. 4 is a plan view of area A2 in FIG. 1 according to an embodiment of the present disclosure;

FIG. 5 is a cross-sectional view taken along line Y-Y′ in area A2 in FIG. 4 according to an embodiment of the present disclosure;

FIG. 6 is a cross-sectional view after secondary cutting is performed along a secondary cutting line in FIG. 4 according to an embodiment of the present disclosure;

FIG. 7 is a cross-sectional view taken along line X-X′ in area A2 in FIG. 4 according to an embodiment of the present disclosure;

FIG. 8 is a cross-sectional view of area A3 in FIG. 1 according to an embodiment of the present disclosure;

FIG. 9 is a cross-sectional view after secondary cutting is performed along a secondary cutting line in FIG. 8 according to an embodiment of the present disclosure;

FIGS. 10A to 10D are plan views after primary and secondary cutting and grinding processes are performed in a method of fabricating the display device according to an embodiment of the present disclosure;

FIGS. 11A to 11C are perspective views after primary and secondary cutting and grinding processes are performed in the method of fabricating the display device according to an embodiment of the present disclosure;

FIGS. 12A to 12C are cross-sectional views after primary and secondary cutting and grinding processes are performed in the method of fabricating the display device according to an embodiment of the present disclosure; and

FIGS. 13A to 13G are views illustrating the method of fabricating the display device according to an embodiment of the present disclosure.

### DETAILED DESCRIPTION OF THE EMBODIMENTS

Advantages and features of the present disclosure, and methods of achieving them will become apparent with reference to the following embodiments, which are described in detail, in conjunction with the accompanying drawings. However, the present disclosure is not limited to the embodiments to be described below and can be implemented in different forms, the embodiments are only provided to completely disclose the present disclosure and completely convey the scope of the present disclosure to those skilled in the art, and the present disclosure is defined by the disclosed claims.

Since the shapes, sizes, proportions, angles, numbers, and the like disclosed in the drawings for describing the embodiments of the present disclosure are only exemplary, the present disclosure is not limited to the illustrated items. Further, in describing the present disclosure, when it is determined that a detailed description of related known technology can unnecessarily obscure the gist of the present disclosure, the detailed description thereof will be omitted.

When “including,” “having,” “consisting of,” and the like mentioned in the present disclosure are used, other parts can be added unless “only” is used. A situation in which a component is expressed in a singular form includes a plural form unless explicitly stated otherwise.

In interpreting the components, it should be understood that an error range is included even when there is no separate explicit description.

In the situation of a description of a positional relationship, for example, when the positional relationship of two parts is described as “on,” “at an upper portion,” “at a lower portion,” “next to,” and the like, one or more other parts can be located between the two parts unless “immediately” or “directly” is used.

A situation where an element or a layer is described as being on another element or layer includes both situations in which the element or layer is directly on the other element or layer and situations in which still another layer or element is interposed between the other element and the element.

Although first, second, and the like are used to describe various components, these components are not limited by these terms. These terms are only used to distinguish one component from another. Accordingly, a first component mentioned below can also be a second component within the technical spirit of the present disclosure. Also, the term “can” includes all meanings and definitions of the term “may.”

The same reference numerals indicate the same components throughout the specification.

The size and thickness of each component shown in the drawings are shown for convenience of description and are not necessarily limited to the sizes and thicknesses of the components shown in the present disclosure.

Features of various embodiments of the present disclosure can be partially or entirely combined with each other, and technically, various linkages and operations are possible, and the embodiments can be implemented independently of each other or together in a related relationship.

Hereinafter, a display device according to an embodiment of the present disclosure will be described with reference to the accompanying drawings.

In the following descriptions, when it is determined that a detailed description of a well-known function or configuration can unnecessarily obscure the principle of the present disclosure, the detailed description thereof will be omitted or briefly described.

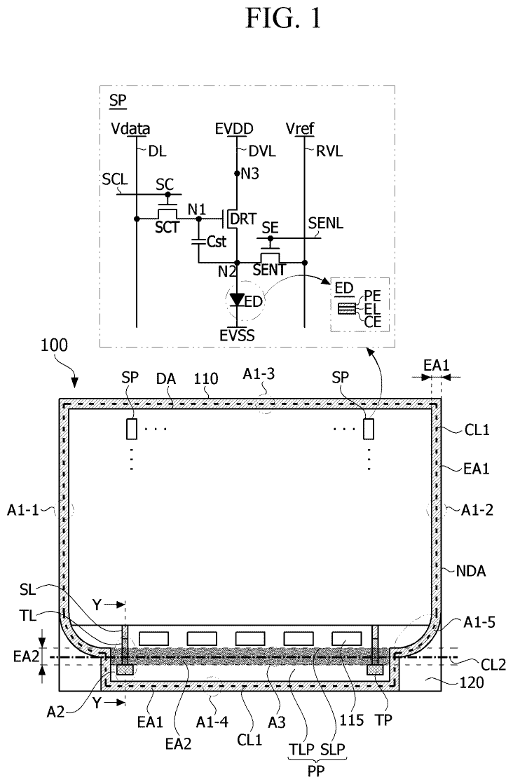

FIG. 1 is a plan view of a display device according to one embodiment of the present disclosure.

Here, the display device in FIG. 1 is in a state in which fabrication is not fully completed yet. In other words, the example in FIG. 1 shows the display device at an intermediate step or transition state before manufacture of the final product has been completed.

Referring to FIG. 1, the display device according to embodiments of the present disclosure can include a display panel 100 including a display area DA and a non-display area NDA, a driving circuit 115 connected to the non-display area NDA of the display panel 100, and the like.

Referring to FIG. 1, in the display panel 100 of the display device according to the embodiments of the present disclosure, a plurality of sub-pixels SP can be disposed in the display area DA, and a plurality of signal lines SL can be disposed to drive the plurality of sub-pixels SP.

The plurality of signal lines SL can further include power lines such as a plurality of driving voltage lines DVL, a plurality of reference voltage lines RVL, and the like.

When the display device according to the embodiments of the present disclosure is a self-luminous display, each of the plurality of sub-pixels SP disposed in the display panel 100 of the display device can include a light-emitting element ED, a driving transistor DRT, a scan transistor SCT, a storage capacitor Cst, and the like.

The light-emitting element ED can include a pixel electrode PE and a common electrode CE, and can include a light-emitting layer EL located between the pixel electrode PE and the common electrode CE.

The pixel electrode PE of the light-emitting element ED can be an electrode disposed in each sub-pixel SP, and the common electrode CE can be an electrode disposed in common in all sub-pixels SP. Here, the pixel electrode PE can be an anode electrode and the common electrode CE can be a cathode electrode. On the other hand, the pixel electrode PE can be a cathode electrode and the common electrode CE can be an anode electrode.

For example, the light-emitting element ED can be an organic light-emitting diode (OLED), an inorganic light-emitting diode (LED), a quantum dot light-emitting element, or the like.

The driving transistor DRT is a transistor for driving the light-emitting element ED, and can include a first node N1, a second node N2, a third node N3, and the like.

The first node N1 of the driving transistor DRT can be a gate node of the driving transistor DRT and can be electrically connected to a source node or drain node of the scan transistor SCT. The second node N2 of the driving transistor DRT can be a source node or drain node of the driving transistor DRT, and can be electrically connected to a source node or drain node of a sensing transistor SENT, and can also be connected to the pixel electrode PE of the light-emitting element ED. The third node N3 of the driving transistor DRT can be electrically connected to the driving voltage line DVL which supplies a driving voltage EVDD.

The scan transistor SCT can be turned on or turned off according to a scan signal SC supplied from a scan signal line SCL which is one type of the gate line GL to control the connection between the data line DL and the first node N1 of the driving transistor DRT.

The storage capacitor Cst can be connected between the first node N1 and the second node N2 of the driving transistor DRT. The storage capacitor Cst is charged with a quantity of electric charge corresponding to a voltage difference between both ends and serves to maintain the voltage difference between both ends for a certain frame time. Accordingly, the sub-pixel SP can emit light for the certain frame time.

Each of the plurality of sub-pixel SP disposed in the display panel 100 of the display device according to embodiments of the present disclosure can further include the sensing transistor SENT. For example, the sensing transistor SENT can be used for sensing characteristics of the sub-pixel SP for performing a compensation operation.

The sensing transistor SENT can be turned on or turned off according to a sense signal SE supplied from a sense signal line SENL which is another type of the gate line GL to control the connection between the reference voltage line RVL and the second node N2 of the driving transistor DRT.

Each of the driving transistor DRT, the scan transistor SCT, and the sensing transistor SENT can be an n-type transistor or a p-type transistor. The storage capacitor Cst may not be a parasitic capacitor (e.g., Cgs or Cgd) which is an internal capacitor which is present between the gate node and the source node (or drain node) of the driving transistor DRT, but can be an external capacitor intentionally designed outside the driving transistor DRT.

The scan signal line SCL and the sense signal line SENL can be different gate lines GL. Alternatively, the scan signal line SCL and the sense signal line SENL can be the same gate line GL. A structure of the sub-pixel SP shown in FIG. 1 is only an example, which can be variously modified by further including one or more transistors or one or more capacitors.

Meanwhile, during a process of fabricating the display panel 100 of the display device, in order to check whether the plurality of signal lines SL properly transmit the signals well or to check whether the plurality of sub-pixels SP can be driven normally and emit light, an auto probe (AP) process can be performed. In other words, during the manufacture of the display device, an auto probe (AP) process can be carried out to determine if there are any defects in the plurality of sub-pixels SP (e.g., a testing step before the final product is completed and shipped).

To this end, as shown in FIG. 1, the display panel 100 includes a substrate 110 including the display area DA and the non-display area NDA, the plurality of signal lines SL disposed in the display area DA of the substrate 110, and a plurality of test lines TL disposed in the non-display area NDA of the substrate 110 and connected to the plurality of signal lines SL. Here, for example, the substrate 110 can be a glass substrate or a plastic substrate. Also, according to embodiments, the substrate 110 can be a flexible substrate.

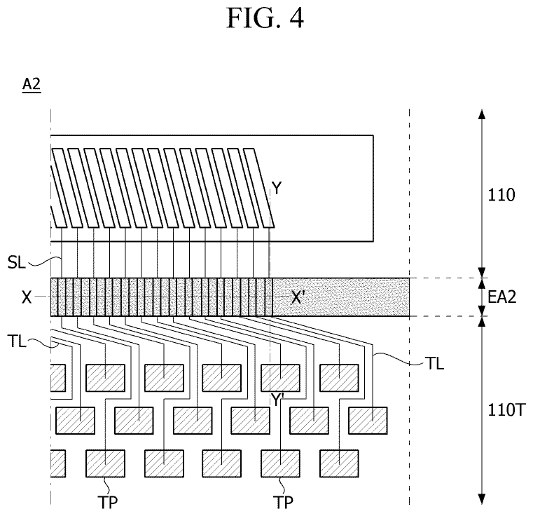

In a state before panel fabrication is completed, there is a test pad substrate 110T integrally connected to the substrate 110, and a plurality of test pads TP can be disposed on the test pad substrate 110T (e.g., FIG. 4). For example, the test pad substrate 110T can be removed after the auto probe (AP) process has been carried out and the manufacturing of the display panel 100 can continue and proceed to completion, which is discussed in more detail below at a later section.

A pad portion PP includes a signal line portion SLP extending to the non-display area NDA and a test line portion TLP connected to the signal line portion SLP. Here, a portion of the test line portion TLP can be removed through a secondary cutting process after performing the auto probe (AP) process. The portion of the test line portion TLP refers to an area of the test line portion TLP including the test pads TP.

The plurality of signal lines SL can include a plurality of data lines DL, a plurality of gate lines GS and SENL, and the like. The plurality of signal lines SL can further include the power lines such as the plurality of driving voltage lines DVL, the plurality of reference voltage lines RVL, and the like. The signal line SL disposed in the display area DA of the substrate 110 can extend to the non-display area NDA and can be electrically connected to the driving circuit 115.

Meanwhile, during a process of fabricating the panel according to the embodiments of the present disclosure, for process simplification or the like, a test structure can be designed so that the test pads TP are disposed outside the display panel 100 after the panel fabrication is completed. To this end, embodiments of the present disclosure disclose a unique method of fabricating a display device (display panel), and a substrate etching structure and an etching stopper structure which are appropriate thereto.

A process of fabricating the display device according to embodiments of the present disclosure can be performed in a mother substrate fabrication process, a primary cutting process, an auto probe process, a secondary cutting process, a grinding process, a module input process, and the like.

Referring to FIG. 1, the mother substrate fabrication process can be a process of forming various types of metal corresponding to various electrodes or lines and various insulating films on the mother substrate. In this situation, the signal lines SL, the test lines TL, the test pads TP, and the like can be patterned on the mother substrate for each panel unit area.

During the mother substrate fabrication process, an etching area (hereinafter, referred to as an etching area) of the mother substrate can be defined for each panel unit area. The etching area may include a first etching area EA1 and a second etching area EA2.

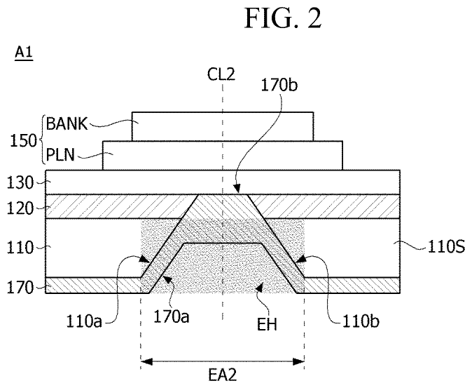

Accordingly, since the etching hole EH is formed in the first and second etching areas EA1 and EA2 of mother substrate in each panel unit area, the substrate 110 and an outer side substrate (e.g., 110S in FIG. 2) can be formed in the first etching area EA1 of the mother substrate. Also, a test pad substrate 110T can be formed in the second etching area EA2 of the mother substrate in a state of being spaced apart from the substrate 110.

The first etching area EA1 of the mother substrate includes four main surfaces of the display panel 100, and first to fifth areas A1-1 to A1-5 can be formed in the non-display area NDA surrounding the display area DA. The first to fifth areas A1-1 to A1-5 can be referred to as an area A1 for convenience of description.

Among the first to fifth areas A1-1 to A1-5, the first to fourth areas A1-1 to A1-4 can correspond to the first etching area EA1 in the non-display area NDA located at first to fourth surfaces surrounding the display area DA of the display panel 100.

Further, the fifth area A1-5 can correspond to the etching area EA located in contact with the outside of the pad portions PP in the fourth area A1-4 and the facing first and second areas A1-1 and A1-2.

In addition, the first etching area EA1 of the mother substrate includes a secondary cutting line CL2 formed on the pad portions PP.

In addition, a trimming line can be formed inside the test line portion TLP at a certain distance from the secondary cutting line CL2 formed in the etching area EA of the mother substrate. Because the trimming line is defined at a certain distance away from the secondary cutting line CL2, it is possible to make a design that includes a grinding margin at the trimming line. In other words, the trimming line is located closer to the display area DA than the secondary cutting line CL2, in which the portion between the secondary cutting line CL2 and the trimming line can be safely and accurately removed during a grinding process.

Referring to FIG. 1, a primary cutting line CL1 can be formed in the first etching area EA1, and the secondary cutting line CL2 can be formed in the second etching area EA2. For example, the portion of the substrate located outside of the primary cutting line CL1 can be removed during a first cutting step, and then another portion of the substrate located between the primary cutting line CL1 and the secondary cutting line CL2 can be removed later during a second cutting step that cuts along the secondary cutting line CL2 (e.g., after testing has been completed via the auto probe (AP) process).

The primary cutting line CL1 includes the first to third areas A1-1 to A1-3 located in the non-display area NDA surrounding three surfaces of the display area DA of the display panel 10, the fourth area A1-4 located outside the pad portion PP, and the fifth area A1-5 connected between the first and second areas A1-1 and A1-2 facing each other and both ends of the fourth area A1-4.

The first to fourth areas A1-1 to A1-4 can have a straight line shape, and the fifth area A1-5 can have a rounded curved shape. However, embodiments of the present disclosure are not necessarily limited thereto.

Further, an etch stop layer 120 is disposed on an upper portion of the substrate 110 overlapping with the etching area EA. Specifically, the etch stop layer 120 is disposed on an upper portion of the substrate 110 overlapping with the first to fourth areas A1-1 to A1-4. Further, the etch stop layer 120 is also disposed on an upper portion of the substrate 110 overlapping with corner areas formed by the fifth area A1-5 and both sides of the fourth area A1-4.

The fifth area A1-5 of the primary cutting line CL1 can be located outside the signal line portion SLP of the pad portion PP.

In embodiments of the present disclosure, the substrate 110 can be a substrate included in the display panel 100 in a state in which panel fabrication is completed, and the test pad substrate 110T can be a substrate which is present only during the panel fabrication process and not present when panel fabrication is completed. The substrate 110 and the test pad substrate 110T can be components of the mother substrate that are later separated from each other by an etching process during the panel fabrication process.

Referring to FIG. 1, the second etching area EA2 of the mother substrate refers to an area between the substrate 110 and the test pad substrate 110T, and the second etching area EA2 can be formed at a position corresponding to the secondary cutting line CL2 where secondary cutting will be performed.

The test pads TP for the auto probe are disposed on the test pad substrate 110T, and the test lines TL disposed on the substrate 110 and the test pad substrate 110T can be connected to the test pads TP for testing the subpixels in the display panel.

Since the test pad substrate 110T is a substrate which is present only during the panel fabrication process and not present in the state when panel fabrication is completed, the test pads TP disposed on the test pad substrate 110T are also not present in the final display panel 100 after panel fabrication is completed. In other words, the portions of the substrate that are located outside of the primary cutting line CL1 and the secondary cutting line CL2 are cut away and removed from the final product.

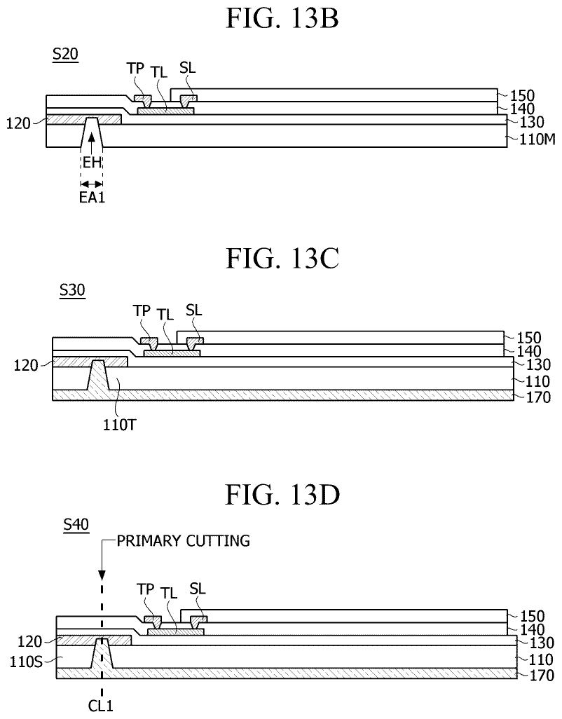

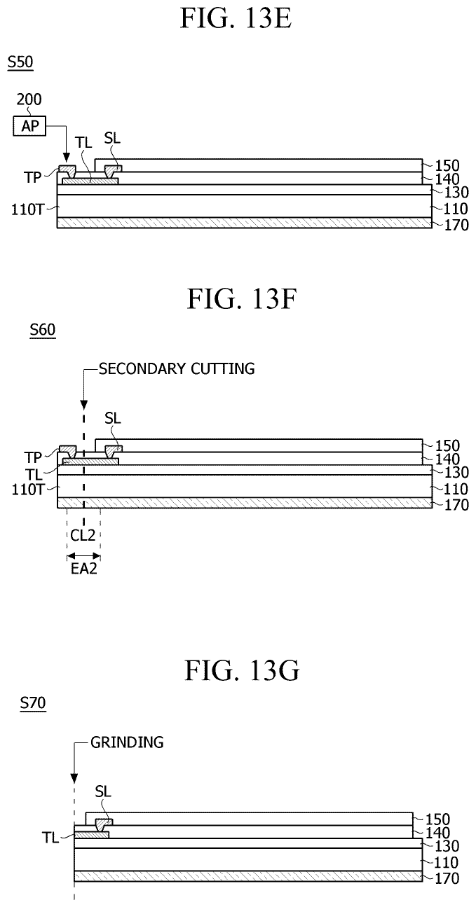

As the mother substrate is cut along the primary cutting line CL1 in the primary cutting process, the test pad substrate 10T is not present in the mother substrate (e.g., 110M in FIG. 13A).

The primary cutting process can be a process of separating a plurality of display panels 100 from the mother substrate by cutting the mother substrate along the primary cutting line CL1. For example, multiple display panels can be formed on a same mother substrate and then divided from each other by cutting along the primary cutting line CL1 that extends around each individual display panel.

After the primary cutting process is completed, the substrate 110 and the test pad substrate 110T can be present as a set for each panel unit.

After the primary cutting process is completed, the test pads TP for the auto probe are disposed on the test pad substrate 110T adjacent to the substrate 110 of the separated display panel 100, and the test lines TL disposed on the substrate 110 and the test pad substrate 110T can still be present in a state of being connected to the test pads TP.

Referring to FIG. 1, in the secondary cutting process, after the auto probe process is completed, as the display panel 100 is cut along the secondary cutting line CL2 corresponding to the second etching area EA2 of the substrate 110, the substrate 110 and the test pad substrate 110T can be separated from each other (e.g., the test pad substrate 110T can be removed).

Here, the secondary cutting line CL2 can correspond to the second etching area EA2, that is, a hole forming area. The secondary cutting line CL2 can correspond to an outer edge of the display panel 100 in a state in which panel fabrication is finally completed or near completion.

In the grinding process, after the test pad substrate 110T is cut away and separated from the substrate 110 through the secondary cutting process, a portion of the substrate 110 where the test pad substrate 110T is cut can be grinded away safely and accurately.

A module input process can be a process that completes the fabrication of the display panel 100 and the display device after the secondary cutting process.

During the process of fabricating the display panel 100 according to embodiments of the present disclosure, a position of the secondary cutting line CL2 where the secondary cutting process is performed can be between the substrate 110 and the test pad substrate 110T.

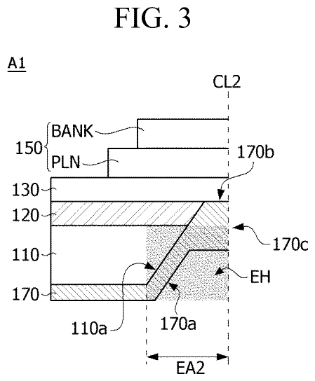

A structure in which the display device according to an embodiment of the present disclosure is cut along the primary cutting line will be described with reference to FIGS. 2 and 3.

FIG. 2 is a cross-sectional view of area A1 in FIG. 1 according to an embodiment of the present disclosure, and FIG. 3 is a cross-sectional view after the primary cutting is performed along the primary cutting line in FIG. 2 according to an embodiment of the present disclosure.

Referring to FIGS. 2 and 3, area A1 is an area primarily cut along the primary cutting line CL1.

Referring to FIG. 2, area A1 of the display panel 100 in a state before the secondary cutting process is performed can include the substrate 110 including the display area DA and the non-display area NDA, the etch stop layer 120 disposed on the substrate 110, the buffer layer 130 disposed on the etch stop layer 120 and a back coating film 170 disposed on a rear surface and outer side surfaces of the substrate 110. The buffer layer 130 may perform the same function as the etch stopper layer 120. And, as another embodiment, the buffer layer 130 may not be disposed on the etch stopper layer 120. However, the present specification is not limited thereto.

In the display panel 100 in a state before the secondary cutting process is performed, the etch stopper layer 120 may be formed with a groove by a partial thickness or may be completely perforated. The buffer layer 130 may not have a groove by etching or may be formed by etching to a predetermined height from the rear surface. However, embodiments of the present disclosure are not limited thereto.

In the display panel 100 in the state before the secondary cutting process is performed, the back coating film 170 can include an organic film.

Since an etching hole EH is formed in the display panel 100 in the state before the secondary cutting process is performed through an etching process, the mother substrate can be separated into the substrate 110 and an outer side substrate 110S.

In the display panel 100 in the state before the secondary cutting process is performed, the etch stop layer 120 can have a through hole formed by the etching process.

In the display panel 100 in the state before the secondary cutting process is performed, a side surface 110a of the substrate 110 and a side surface 110b of the outer side substrate 110S have a first tapered shape or a second tapered shape in the etching hole EH. For example, the side surface 110a of the substrate 110 and the side surface 110b of the outer side substrate 110S can be inclined side surfaces.

In the display panel 100, in the state before the secondary cutting process is performed, the back coating film 170 can be disposed along an inner side surface of the etching hole EH.

In the display panel 100, in the state before the secondary cutting process is performed, the back coating film 170 can be disposed on the rear surface of the substrate 110 and a rear surface of the outer side substrate 110S. The back coating film 170 can also be disposed on the side surface 110a of the substrate 110 and a side surface 110b of the outer side substrate 110S in the etching hole EH.

The display panel 100 in the state before the secondary cutting process is performed can further include a buffer layer 130 disposed on the etch stop layer 120. The etch stop layer 120 can include an inorganic film, and the buffer layer 130 can include an organic film.

A partial upper surface 170b of the back coating film 170 can be in contact with a partial rear surface of the buffer layer 130 through the through hole of the etch stop layer 120.

Area A1 of the display panel 100 in a state in which the primary cutting process is completed includes the substrate 110 including the display area DA and the non-display area NDA, the etch stop layer 120 and the buffer layer 130 disposed on the substrate 110, and the back coating film 170 disposed on the rear surface and outer side surfaces of the substrate 110.

Referring to FIG. 3, in the display panel 100 in the state in which the primary cutting process is completed, the back coating film 170 can include an organic film.

In the display panel 100 in the state in which the primary cutting process is completed, an outer side edge 170c of the back coating film 170 can be located further outside of or away from a side surface edge 110a of the substrate 110. Also, the side surface edge 110a of the substrate 110 can be inclined at a certain angle.

In the display panel 100 in the state in which the primary cutting process is completed, the side surface edge 110a of the substrate 110 can have a first tapered shape or a second tapered shape. That is, the side surface edge 110a of the substrate 110 can have a sharp cross-section or be tapered to a point.

In the display panel 100 in the state in which the primary cutting process is completed, a side surface edge 170a of the back coating film 170 can have the same tapered shape as the side surface edge 110a of the substrate 110 (e.g., a same inclined angle).

FIG. 4 is a plan view of area A2 in FIG. 1 according to an embodiment of the present disclosure.

Referring to FIG. 4, in area A2 in FIGS. 1 and 2, the substrate 110 and the test pad substrate 110T can be present integrally, and the second etching area EA2 can be present between the substrate 110 and the test pad substrate 110T.

The plurality of signal lines SL can be disposed on the substrate 110, and the plurality of test pads TP can be disposed on the test pad substrate 110T.

The plurality of test lines TL can connect to the plurality of signal lines SL disposed on the substrate 110 and the plurality of test pads TP can be disposed on the test pad substrate 110T in a one-to-one manner.

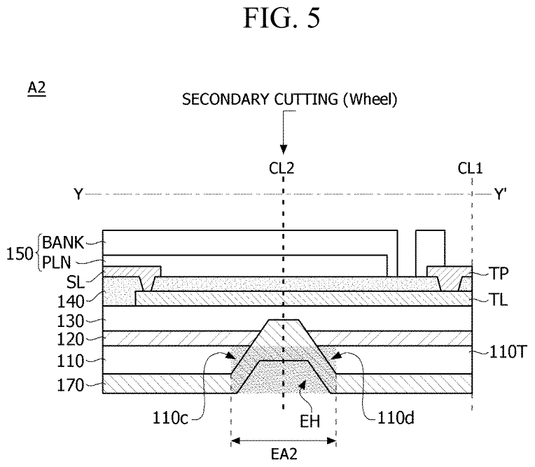

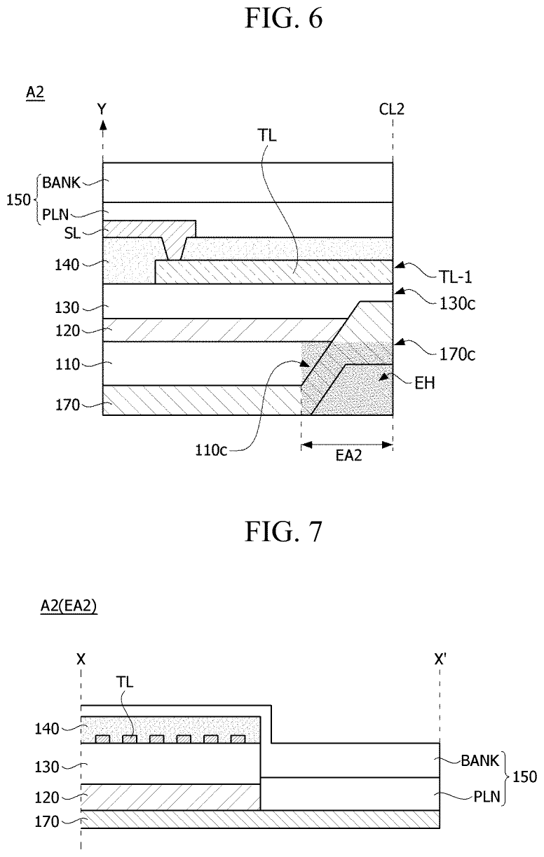

Hereinafter, a cross-sectional view taken along line Y-Y′ in FIG. 4 will be described with reference to FIGS. 5 and 6.

FIG. 5 is a cross-sectional view taken along line Y-Y′ in area A2 in FIG. 4, and FIG. 6 is a cross-sectional view after secondary cutting is performed along the secondary cutting line in FIG. 4 according to an embodiment of the present disclosure.

Referring to FIG. 5, in the display panel 100 in the state before the secondary cutting process is performed, the second etching area EA2 can be formed between the substrate 110 and the test pad substrate 110T by the etching process of the mother substrate. In this case, the side surface 110c of the substrate 110 and the side surface 110d of the outer side substrate 110T may have a tapered shape inside the etching hole EH of the second etching region EA2.

In the display panel 100, in the state before the secondary cutting process is performed, the back coating film 170 can be coated on a rear surface of the mother substrate where the second etching area EA2 is formed. Accordingly, the back coating film 170 can be coated on the rear surface 110d of the substrate 110 and the rear surface of the test pad substrate 110T. In this situation, the back coating film 170 can also be coated on a side surface 110a of the substrate 110 and a side surface 110b of the outer side substrate (110S in FIG. 2) in the etching hole EH of the first etching area EA1 in the first to fifth areas A1-1 to A1-5 during the primary cutting process.

The display panel 100, in the state before the secondary cutting process is performed, can further include a buffer layer 130 between the test lines TL and the test pad substrate 110T. The buffer layer 130 is an insulating film and can be an organic film or an inorganic insulating film. However, embodiments of the present disclosure are not necessarily limited thereto. In this situation, the etch stop layer 120 is not present between the test lines TL and the test pad substrate 110T. Specifically, the etch stop layer 120 may be disposed only on the substrate 110 and the outer side substrate 110S located in the first to fifth areas A1-1 to A1-5 located in the non-display area NDA of the display panel 100 overlapping with the primary cutting line CL1 cut during the primary cutting process.

Further, the etch stop layer 120 can also be disposed in an area between the fifth area A1-5 and outer portions of both sides of the pad portion PP in addition to the first to fifth areas A1-1 to A1-5 corresponding to the first etching area EA1 where the primary cutting line CL1 is defined.

Referring to FIG. 6, in the display panel 100 in a state in which the secondary cutting process using a wheel is completed (e.g., the area to the right in FIG. 5 has been removed), the side surface 170c of the back coating film 170 can have the same straight shape as the side surface 110c of the substrate 110. For example, after the secondary cutting process is completed, the side surface 170c (e.g., outer edge) of the back coating film 170 can be flush and parallel with the side surface 110c (e.g., outer edge) of the substrate 110.

In the display panel 100, in the state in which the secondary cutting process is completed, an outer side edge of the test line TL can have a cut surface TL-1 in a cut shape. The cut surface TL-1 of the outer side edge of the test line TL can be aligned with a cut surface, which is the side surface 130c of the buffer layer 130 and a cut surface, which is the outer side surface 170c of the back coating film 170. For example, after the secondary cutting process is completed, the side surface 170c of the back coating film 170, cut surface TL-1 of the outer side edge of the test line TL and the side surface 130c of the buffer layer 130 can all be aligned and flush with each other.

FIG. 7 is a cross-sectional view taken along line X-X′ in area A2 in FIG. 4 according to an embodiment of the present disclosure.

Area A2 in FIG. 7 can include an area crossing the plurality of test lines TL (e.g., an area marked with the line X-X′), and this area can be included in the second etching area EA2.

Referring to FIG. 7, the substrate 110 is present in the second etching area EA2 in area A2. Specifically, in the second etching area EA2 in area A2, since the substrate 110 is not etched through the etching process and is cut through a scribing process using a wheel, a process of etching the substrate 110 can be omitted.

In the second etching area EA2 in area A2, the back coating film 170 can be disposed on the rear surface of the substrate 110, the buffer layer 130 can be disposed on the substrate 110, and the plurality of test lines TL can be disposed on the buffer layer 130.

Further, in the second etching area EA2 in area A2, an inorganic insulating film 140 can be disposed to cover or overlap with the plurality of test lines TL.

An organic film 150 can be disposed on the top and side surfaces of the inorganic insulating film 140. The organic film 150 can include a planarization film PLN and a bank BANK. At a location where there are no test lines TL, the organic film 150 can be disposed on the back coating film 170.

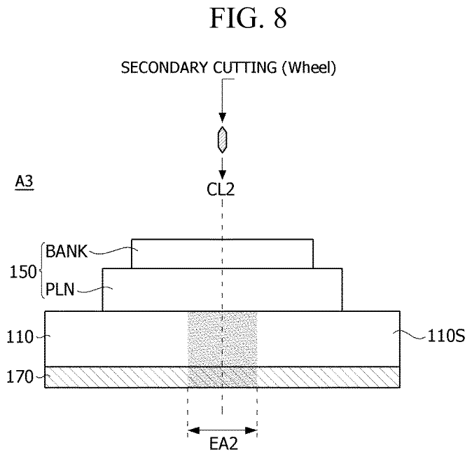

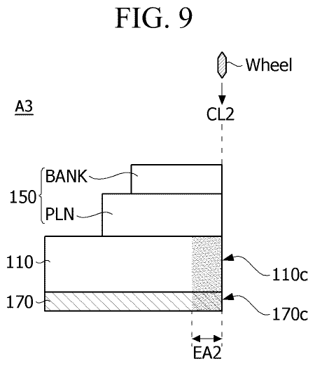

FIG. 8 is a cross-sectional view of area A3 in FIG. 1, and FIG. 9 is a cross-sectional view after secondary cutting is performed along the secondary cutting line in FIG. 8 according to an embodiment of the present disclosure.

Referring to FIG. 8, area A3 of the display panel 100 in the state before the secondary cutting process is performed can include the substrate 110 including the display area DA and the non-display area NDA, a buffer layer (130 of FIG. 7) disposed on the substrate 110, and the back coating film 170 disposed on the rear surface and the outer side surfaces of the substrate 110.

In the display panel 100, in the state before the secondary cutting process is performed, the back coating film 170 can include an organic film.

Referring to FIG. 9, area A3 in the display panel 100 in the state in which the secondary cutting process using a wheel is completed can include the substrate 110 including the display area DA and the non-display area NDA, the organic film 150 disposed on the substrate 110, and the back coating film 170 disposed on the rear surface and the outer side surfaces of the substrate 110.

In the display panel 100 in the state in which the secondary cutting process is completed, the back coating film 170 can include an organic film.

In the display panel 100 in the state in which the secondary cutting process is completed, an outer side edge of the back coating film 170 can be located on the same line as the outer side edge of the substrate 110. For example, the outer edge of the back coating film 170, the outer side edge of the substrate 110 and the outer side edge of the organic film 150 can all be aligned and flush with each other.

In the display panel 100, in the state in which the secondary cutting process is completed, the outer side edge of the back coating film 170 can have the same cross-sectional shape as the outer side edge of the substrate 110, that is, a right angle shape.

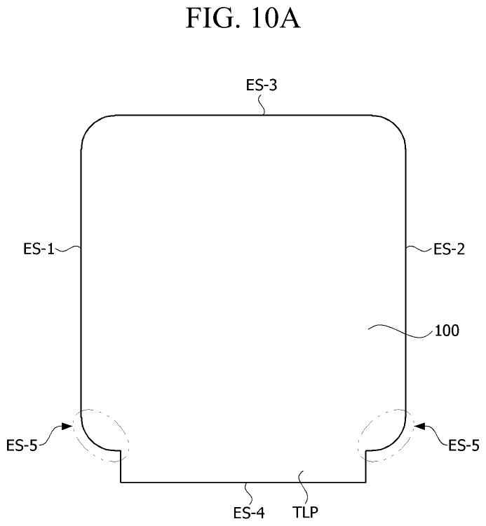

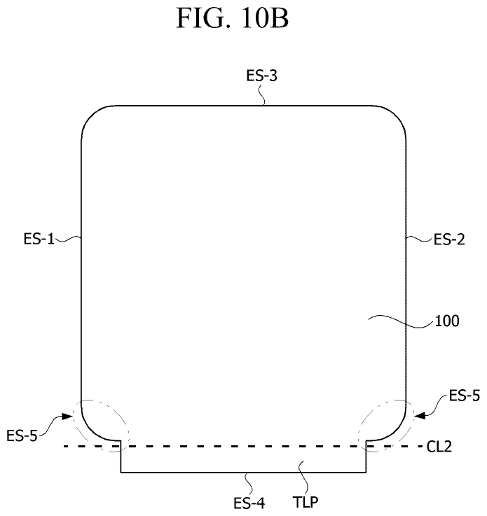

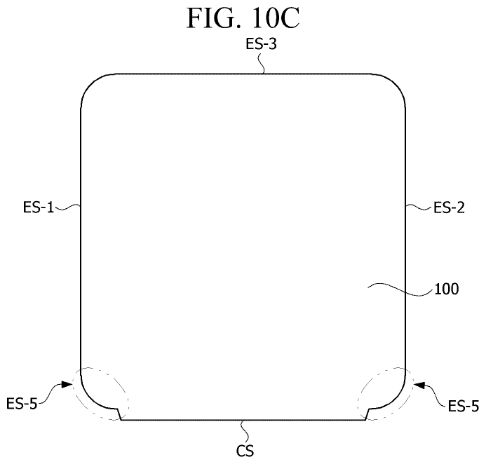

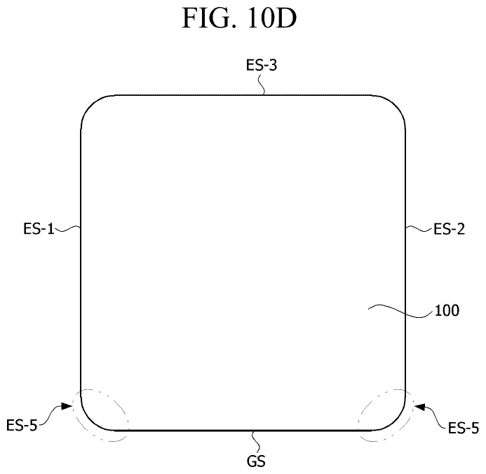

FIGS. 10A to 10D are plan views after primary and secondary cutting and grinding processes are performed in a method of fabricating the display device according to one embodiment of the present disclosure.

Referring to FIG. 10A, the plurality of display panels 100 are separated from the mother substrate by cutting the mother substrate along the primary cutting line (e.g., CL1 in FIG. 1).

In this situation, the display panel 100 includes first to fifth side surface portions ES-1 to ES-5 formed in the non-display area NDA surrounding the display area DA. During primary cutting, cross-sections of the first to fifth side surface portions ES-1 to ES-5 can have sharp shapes. For example, the fifth side surface ES-5 portion can include a first rounded side surface portion and a second rounded side surface portion on opposite sides of the fourth side surface portion ES-4.

The first to third side surface portions ES-1 to ES-3 are areas in the non-display area NDA located on three surfaces surrounding the display area DA of the display panel 100, and the fourth side surface portion ES-4 includes an area outside of the test line portion TLP of the pad portion PP located at the remaining one surface of the display panel 100 (e.g., the fourth side surface portion ES-4 will be removed later, after the auto probe testing process has been completed).

Further, the fifth side surface portion ES-5 includes an area connected between the facing first and second side surface portions ES-1 and ES-2 and the fourth side surface portion ES-4 (e.g., a first rounded side surface portion and a second rounded side surface portion on opposite sides of the fourth side surface portion ES-4). Specifically, the first to fourth side surface portions ES-1 to ES-4 can be formed in a straight line shape. Further, the fifth side surface portion ES-5 is a round part and can have a rounded curved shape. However, embodiments of the present disclosure are not necessarily limited thereto.

Further, a portion of the fifth side surface portion ES-5 can be grinded away after the secondary cutting process in FIG. 10B. That is, the fifth side surface portion ES-5 can include a stepped portion including both a sharp surface (e.g., a sharp corner or notched portion) and a rounded surface after the grinding process. In other words, the fifth side surface portion ES-5 can include a rounded corner area in which one part of the rounded corner area has a sharp edge surface and another part of the rounded corner area has a rounded edge surface (e.g., the portion located closer to the fourth side portion ES-4). The fifth side surface portion ES-5 can have a sharp surface formed during the etching process of etching the substrate prior to the primary cutting process and a rounded surface formed after the grinding process performed after the secondary cutting process. That is, the stepped portion of the fifth side surface portion ES-5 can include a tapered sharp etched surface and a rounded grinding surface.

Referring to FIG. 10B, in a state in which the display panel 100 is separated from the mother substrate through the primary cutting process, the auto probe process is performed (e.g., during which the subpixels can be tested for defects), and then the secondary cutting line CL2 is secondarily cut, in order to cut away the test pad (TP in FIG. 1).

In this situation, the secondary cutting process is performed along the secondary cutting line CL2 through the scribing process using a wheel to cut and separate the test pad TP of the test line portion TLP from the display panel 100.

The secondary cutting line CL2 can be defined on the pad portion PP in the non-display area NDA and can be formed along a longitudinal direction of the display panel 100 by crossing between the signal lines SL and the test lines TL.

Further, both ends of the secondary cutting line CL2 are in contact with one end of the round part, which is the round fifth side surface portion ES-5.

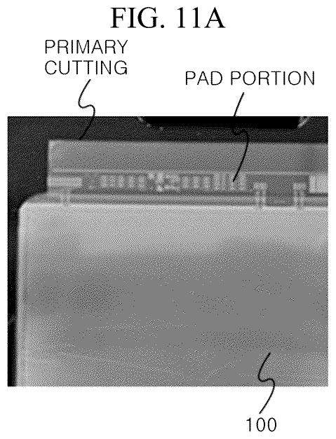

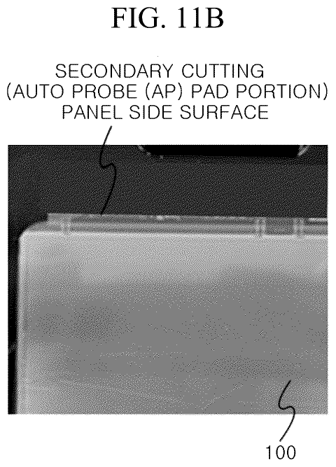

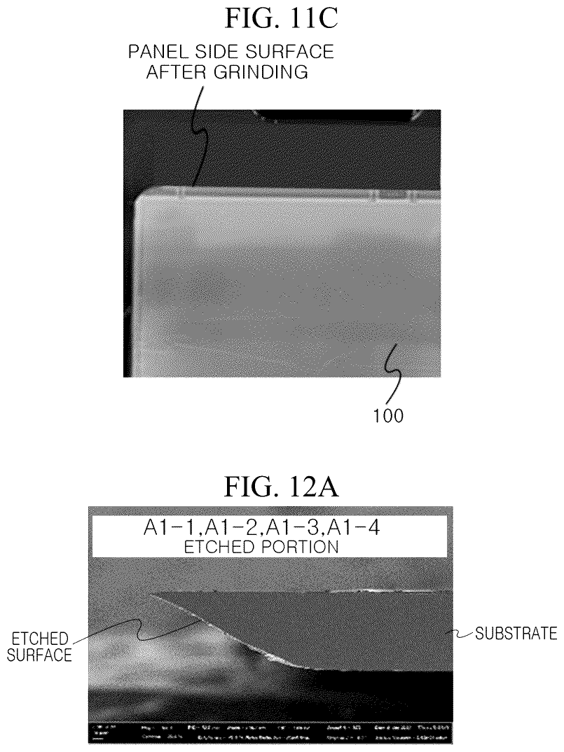

However, immediately after the secondary cutting process is completed, a sharp nub or tab portion can remain that extends from one end of the display panel (e.g., see FIG. 11B). Referring to FIG. 10C, after the secondary cutting process, a secondarily-cut cutting portion CS, that is, a portion from which the test pad TP is removed, is grinded away in order to provide a more robust edge along the bottom fourth side of the display panel 100 (e.g., see FIG. 11C).

In this situation, during the grinding process, since a step is generated at a contact point of the etched surface and the grinding surface of the fifth side surface portion ES-5, a stepped portion is formed.

Referring to FIG. 10D, the cutting portion CS forms a grinding portion GS through the grinding process, and the stepped portion of the fifth side surface portion ES-5 adjacent to both sides of the grinding portion GS can be formed by combining a tapered sharp etched surface and a round grinding surface.

Accordingly, since the tapered sharp etched surface and the round grinding surface are formed in the fifth side surface portion which is the stepped portion in the combined manner as three surfaces of the display panel 100 are etched through a chemical etching process and then cut, and the test pad of the test line portion of the pad portion, which is the remaining one surface, is cut through the scribing process using a wheel and the cut portion is ground, a display device with a robust structure can be fabricated.

FIGS. 11A to 11C are perspective views after primary and secondary cutting and grinding processes are performed in the method of fabricating the display device according to one embodiment of the present disclosure.

Referring to FIG. 11A, the test pad substrate 110T is spaced apart from the substrate 110 in the display panel 100 in a state before panel fabrication is completed. A plurality of test pads TP can be disposed on the test pad substrate 110T.

After the primary cutting process, the test pads TP for the auto probe are disposed on the test pad substrate 110T adjacent to the substrate 110 of the separated display panel 100, and the substrate 110 and the test lines TL disposed on the test pad substrate 110T can still be present in the state of being connected to the test pads TP.

Referring to FIG. 11B, in the secondary cutting process, after the auto probe process is completed, as the display panel 100 is cut along the secondary cutting line CL2 corresponding to the second etching area EA2 of the substrate 110, the substrate 110 and the test pad substrate 110T can be separated from each other (e.g., the test pad area can be cut away and removed).

Referring to FIG. 11C, after the test pad substrate 110T is cut and separated away from the substrate 110 through the secondary cutting process by performing the grinding process, the portion of the substrate 110 where the test pad substrate 110T is cut can be ground to fabricate a display panel without a stepped portion (e.g., a burr or notched portion can be removed from the side of the display panel 100 where the test pad substrate 110T was previously located).

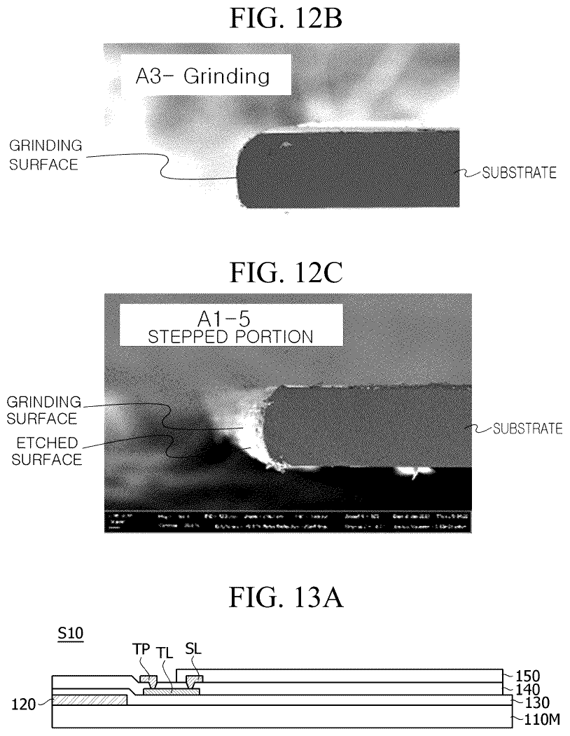

FIGS. 12A to 12C are cross-sectional views after primary and secondary cutting and grinding processes are performed in the method of fabricating the display device according to one embodiment of the present disclosure.

FIG. 12A illustrates a state in which a cross-sectional shape in the first to fourth areas A1-1 to A1-4 is a tapered shape through the primary cutting process. For example, a sharp burr that is tapered to a point may remain along the outer edges after the primary cutting process is performed.

The substrate 110 of the display panel 100 is cut and separated from the mother substrate through the primary cutting process. In this situation, the first to fifth areas (A1-1 to A1-5 in FIG. 1) of the substrate 110 of the display panel 100 have a tapered cross-sectional structure (e.g., a sharp burr along the outer edge).

Referring to FIG. 12B, after the auto probe process is completed, as the display panel 100 is cut along the secondary cutting line CL2 of the substrate 110 through the secondary cutting process to separate the substrate 110 and the test pad substrate 110T and then area A3, which is a secondarily cut portion, is ground, a round grinding surface having an even cross-section is formed.

Further, FIG. 12C illustrates a cross-sectional state of the fifth area A1-5, which shows a cross-sectional shape in which the tapered sharp etched surface formed through the primary cutting process and the round grinding surface formed through the grinding process after the secondary cutting process are combined. That is, a situation in which a portion of the tapered etched surface formed through the primary cutting process is changed into a round shape through the grinding process can be shown. In other words, the cutting process can cause the outer edge to have a sharp burr that remains, then the grinding process can remove the shape burr and turn the outer edge into a rounded edge shape. Also, according to an embodiment, the fifth area A1-5 (e.g., the rounded corner area) can provide a type of transition zone where the sharp tapered edge of the first area A1-1 or the second area A1-2 gradually transitions into the rounded edge at area A3. In other words, an abrupt transition between the two different types of edges can be avoided.

Accordingly, in the display device according to one embodiment of the present disclosure, as the stepped portion is formed in the fifth area A1-5 where the tapered sharp etched surface formed through the primary cutting process and the round grinding surface formed through the grinding process after the primary cutting process are combined, the contact point between the etched surface and the grinding surface can be minimized, making it possible to fabricate a display panel with a robust structure.

FIGS. 13A to 13G are views illustrating the method of fabricating the display device according to one embodiment of the present disclosure.

Referring to FIGS. 13A to 13G, the process of fabricating the display device according to embodiments of the present disclosure can include mother substrate fabrication processes (S10, S20, and S30), a primary cutting process (S40), an auto probe process (S50), a secondary cutting process (S60), a grinding process (S70), a module input process, and the like.

Referring to FIG. 13A, in operation S10 among the mother substrate fabrication processes, various types of metal corresponding to various electrodes or lines and various insulating films can be formed on a mother substrate 110M. In this situation, the signal lines SL, the test lines TL, the test pads TP, and the like can be patterned on the mother substrate 110M for each panel unit area.

In operation S10 among the mother substrate fabrication processes, the etch stop layer 120 can be deposited between the mother substrate 110M and the test lines TL. The etch stop layer 120 can be an inorganic film including an inorganic material.

Next, referring to FIG. 13B, in operation S20 (an etching process operation) among the mother substrate fabrication processes, the etching area EA of the mother substrate 110M can be etched for each panel unit area. Accordingly, the etching hole EH is formed in the first etching area EA1 of the mother substrate 110M for each panel unit area. According to an embodiment, a plurality of etching holes EH can be provided along the outer perimeter of the each panel unit area to create a type of perforation cutting line, but embodiments are not limited thereto. However, according to another embodiment, the etching hole EH can be provided as single continuous trench, groove or hole along the outer perimeter of the each panel unit area.

In this situation, the first etching area EA1 of the mother substrate 110M can be formed at a portion outside of the test pad substrate 110T provided in the substrate 110.

The first etching area EA1 of the mother substrate 110M refers to areas outside of the substrate 110 and the test pad substrate 110T, and no substrate is present in this first etching area EA1. The etching hole EH of the mother substrate 110M formed in the first etching area EA1 can be formed at a position corresponding to the primary cutting line CL1 to be primarily cut. As described above, since no substrate is present at the primary cutting line CL1 to be primarily cut, the primary cutting process can be facilitated.

Next, in operation S20 (etching process step) among the mother substrate fabrication processes, there is a possibility that only a small groove is formed by etching, and a through hole is not formed in the etch stop layer 120 (e.g., the etching hole EH can extend all the through substrate 110 but may not extend all the way through the etch stop layer 120).

Next, referring to FIG. 13C, in operation S30 (a back coating process operation) among the mother substrate fabrication processes, the back coating film 170 can be coated on rear surfaces of the substrate 110 and the test pad substrate 110T. The back coating film 170 can include an organic material. For example, the back coating film 170 can be coated across the entire rear surface of the substrate 110 and the test pad substrate 110T and can fill the etching hole EH.

Next, referring to FIG. 13D, in operation S40 which is a primary cutting operation, an outer portion (110S, that is, the outer side substrate) of the substrate 110 can be cut along the primary cutting line CL1.

Next, referring to FIG. 13E, in operation S50 which is an auto probe process operation, a test signal can be supplied to the signal lines SL through the test pads TP, and a test (lighting test) to determine whether the sub-pixels (SP in FIG. 1) are normally driven and emit light can be performed using auto probe equipment 200 (e.g., the sub-pixels can be tested for defects).

Next, referring to FIG. 13F, in operation S60 which is a secondary cutting process operation, as the display panel 100 is cut along the secondary cutting line CL2 corresponding to the second etching area EA2 of the substrate 110, the substrate 110 and the test pad substrate 110T can be separated from each other. Here, the secondary cutting line CL2 can correspond to the second etching EA2. The secondary cutting line CL2 can correspond to the outer edge of the display panel 100 in the state in which panel fabrication is finally completed or near completion.

Next, referring to FIG. 13G, in operation S70 which is a grinding process operation, a portion where the test pad substrate 110T is cut through the secondary cutting process is ground. In this situation, a portion of the tapered sharp etched surface formed in the fifth area (area A1-5 in FIG. 1) through the primary cutting process can be changed into a round shape through the grinding process. That is, a stepped portion formed in the fifth area can be formed by combining a tapered sharp etched surface and a round grinding surface (e.g., a remaining burr or tab portion can be removed, and the outer edge can be rounded via the grinding).

Next, as a module input process is performed based on the substrate 110 separated from the test pad substrate 110T, the process of fabricating the display panel 100 and the display device can be completed.

Accordingly, in the display device according to one embodiment of the present disclosure, as the stepped portion is formed in the fifth area A1-5 where the tapered sharp etched surface formed through the primary cutting process and the round grinding surface formed through the grinding process after the primary cutting process are combined, the contact point between the etched surface and the grinding surface can be minimized (e.g., a smoother transition can be provided between these two different areas), making it possible to fabricate a display panel with a robust structure.

According to the present disclosure, as three surfaces of the display panel are etched through a chemical etching process and then cut, and a test pad portion, which is the remaining one surface, is cut through a scribing process using a wheel and then the cut portion is ground, a display device with a robust structure can be fabricated.

According to the present disclosure, as three surfaces of the display panel are etched through the chemical etching process and then cut, the test pad, which is the remaining one surface, is cut through the scribing process using a wheel and then the cut portion where the test pad is cut is ground, during the grinding process, etching and regular grinding which reflect a heterogeneous contour can be advantageous to minimize a contact point between the etched surface and the grinding surface. In other words, a better transition can be provided between the etched surface and the grinding surface.

According to the present disclosure, since the test pad is cut through a cutting process using a wheel without using chemical etching technology, and thus over-etching does not occur when the pad portion is etched, the possibility of moisture permeation through lines can be reduced (e.g., a strong and more robust edge can be provided which is more resistant to moisture permeation, which can extend the lifespan of the device).

According to the present disclosure, since the test pad is cut through the cutting process using a wheel when the test pad portion is etched, line disconnection which can occur when the test pad is etched through the chemical etching process can be reduced.

Since the contents of the specification described in the problem to be solved, the means to solve the problem, and the effects described above do not specify the essential features of the claims, the scope of the claims is not limited by items described in the contents of the specification.

Although the embodiments have been described in more detail with reference to the accompanying drawings, the present disclosure is not necessarily limited to these embodiments, and can be variously modified without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, the above-described embodiments should be understood in all respects as illustrative and not restrictive.

The display device according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device s, a theater display device, a television, a wallpaper apparatus, a signage apparatus, a gaming apparatus, a laptop PC, a monitor, a camera, a camcorder, a home appliance, and the like.

Display devices according to various embodiments of the present disclosure can be described as follows.

A display device according to one embodiment of the present disclosure can comprise a substrate including a display area and a non-display area surrounding the display area, a pad portion disposed in the non-display area of the substrate, first, second, and third side surface portions located in the non-display area adjacent to the display area of the substrate, a grinding portion located in the pad portion of the substrate, and a stepped portion located between the first and second side surface portions facing each other and the grinding portion, in which the stepped portion includes an etched surface and a grinding surface.

A display device according to one or more embodiment of the present disclosure can include a back coating film disposed on a rear surface of the substrate.

According to one or more embodiment of the present disclosure, an etch stop layer can be disposed on the substrate adjacent to the first to third side surface portions and the stepped portion.

A display device according to one or more embodiment of the present disclosure can include the first to third side surface portions have etched surfaces and the grinding portion has a ground cut surface.

A display device according to one or more embodiment of the present disclosure can include a substrate including a display area and a non-display area surrounding the display area, a pad portion disposed in the non-display area, first to third side surface portions located in the non-display area excluding the pad portion and a round side surface portion located in the pad portion, and a stepped portion located between the first and second side surface portions facing each other and the round side surface portion, and an etch stop layer disposed on the substrate adjacent to the first to third side surface portions and the stepped portion, and a back coating film disposed on a rear surface and an outer side surface of the substrate.

According to one or more embodiment of the present disclosure, the stepped portion can be located between each of one ends of the first and second side surface portions facing each other and each of both ends of the round side surface portion.

A display device according to one or more embodiment of the present disclosure can include the first to third side surface portions have sharp etched side surfaces, and the round side surface portion has a round ground side surface.

A display device according to one or more embodiment of the present disclosure, the stepped portion can include a tapered sharp side surface and a round ground side surface.

A method of fabricating a display device according to one or more embodiment of the present invention can include disposing a plurality of display panels on a mother substrate, primarily cutting the plurality of display panels having first to fourth side surface portions and round parts to separate the plurality of display panels from the mother substrate, secondarily cutting a test pad of the separated display panel and grinding a portion of the display panel where the test pad is cut.

A display device according to one or more embodiment of the present disclosure, the round part can include a stepped portion having a sharp side surface and a round side surface through the grinding.

A display device according to one or more embodiment of the present disclosure, the sharp side surface is formed during primary cutting of the first to fourth side surface portions of the display panel.

A display device according to one or more embodiment of the present disclosure, the round side surface of the stepped portion is formed in the grinding of the portion of the display panel where the test pad is cut.

A display device according to one or more embodiment of the present disclosure, the primary cutting of the first to fourth side surface portions and the round parts of the plurality of display panels can further include a process of etching a rear surface of the mother substrate corresponding to the first to fourth side surface portions and the round parts to form an etching hole, and a process of cutting along a cutting line corresponding to the etching hole.

A display device according to one or more embodiment of the present disclosure, an etch stop layer can be disposed on a substrate of each of the plurality of display panels adjacent to the first to fourth side surface portions and the round parts.

A display device according to one or more embodiment of the present disclosure, the etch stop layer can be disposed on the substrate corresponding to a corner area between the first side surface portion and the fourth side surface portion adjacent to the round parts and a corner area between the second side surface portion and the fourth side surface portion adjacent to the round parts.

A display device according to one or more embodiment of the present disclosure, the primary and secondary cutting can be performed by cutting using a laser or cutting using a wheel.

According to an embodiment of the present disclosure, a method of fabricating a display device can include disposing a plurality of display panels on a mother substrate, performing a primary cutting process cutting the plurality of display panels having first, second, third and fourth side surface portions and round parts to separate a display panel among the plurality of display panels away from the mother substrate, the display panel including a test pad, performing a secondary cutting process cutting the test pad off of the display panel, and grinding a portion of the display panel at a location where the test pad was cut away from the display panel.

According to an embodiment of the present disclosure, the round part of the display panel includes a stepped portion having a sharp side surface and a round side surface through the grinding.

According to an embodiment of the present disclosure, the sharp side surface is formed during the primary cutting process including cutting of the first, second, third and fourth side surface portions of the display panel.

According to another embodiment of the present disclosure, the primary cutting of the first, second, third and fourth side surface portions and the round parts of the plurality of display panels further includes etching a rear surface of the mother substrate corresponding to the first, second, third and fourth side surface portions and the round parts to form an etching hole that extends through the mother substrate, and cutting along a cutting line corresponding to the etching hole.

According to an embodiment of the present disclosure, an etch stop layer is disposed on a substrate of each of the plurality of display panels adjacent to the first, second, third and fourth side surface portions and the round parts.

According to another embodiment of the present disclosure, the etch stop layer is disposed on the substrate corresponding to a corner area between the first side surface portion and the fourth side surface portion adjacent to the round parts and a corner area between the second side surface portion and the fourth side surface portion adjacent to the round parts.

According to an embodiment of the present disclosure, the primary cutting process and the secondary cutting process are performed by cutting using a laser or a wheel.

Since the contents of the specification described in the above-described technical problem, technical solution, and advantageous effects do not specify the essential features of the claims, the scope of the claims is not limited by the items described in the contents of the specification.

Although embodiments of the present invention have been described in detail with reference to the accompanying drawings, the present invention is not necessarily limited to these embodiments, and various modifications can be carried out without departing from the technical spirit of the present invention. Therefore, the embodiments disclosed in the present invention are not intended to limit the technical spirit of the present invention, but for describing it, and the scope of the technical spirit of the present invention is not limited by these embodiments. It should be understood that the above-described embodiments are illustrative and not restrictive in all respects.

What is claimed is:

1. A display device comprising:
a substrate including a display area configured to display image and a non-display area adjacent to the display area;
a pad portion disposed in the non-display area of the substrate;
first, second and third side surface portions located in the non-display area adjacent to the display area of the substrate;
a grinding portion located in the pad portion of the substrate; and
a stepped portion located between the grinding portion and at least one of the first and second side surface portions,
wherein the stepped portion includes an etched surface and a grinding surface.

2. The display device of claim 1, further comprising a back coating film disposed on a rear surface of the substrate.

3. The display device of claim 1, further comprising an etch stop layer disposed on the substrate adjacent to the first to third side surface portions and the stepped portion.

4. The display device of claim 1, wherein the first, second and third side surface portions have etched surfaces, and
wherein the grinding portion has a ground cut surface.

5. A display device comprising:
a substrate including a display area configured to display an image and a non-display area at least partially surrounding the display area;
a pad portion disposed in the non-display area;
first, second, third and fourth side surface portions located in the non-display area, the fourth side surface portion corresponding to the pad portion and having a rounded edge surface;
a rounded corner area located between the fourth side surface portion and at least one of the first and second side surface portions;
an etch stop layer disposed on the substrate adjacent to the first, second and third side surface portions and the rounded corner area; and
a back coating film disposed on a rear surface of the substrate and an outer side surface of the substrate.

6. The display device of claim 5, wherein the first, second and third side surface portions have sharp etched side surfaces.

7. The display device of claim 5, wherein the rounded corner area includes a tapered sharp side surface and a round ground side surface.

8. A display panel comprising:
a plurality of subpixels disposed in a display area of a substrate and a non-display area of the substrate at least partially surrounding the display area;
wherein a first side of the display panel has a first inclined edge, a second side of the display panel has a second inclined edge, and a third side of the display panel has a third inclined edge, and
wherein a fourth side of the display panel has a rounded edge.

9. The display panel of claim 8, wherein a rounded corner area is between the fourth side of the display panel and at least one of the first side of the display panel and the second side of the display panel, and
wherein the rounded corner area has an inclined edge that transitions to a rounded edge.

10. The display panel of claim 8, wherein the rounded corner area transitions from the inclined edge to the rounded edge in a direction toward the fourth side of the display panel.

11. The display panel of claim 8, wherein each of the first, second and third inclined edges of the first, second and third sides of the display panel is tapered to a point in a cross-section view.

12. The display panel of claim 8, further comprising:
a back coating film disposed across a rear surface of the substrate and at least a portion of the first, second and third inclined edges of the first, second and third sides of the display panel.

13. The display panel of claim 12, further comprising:
an etch stop layer disposed on an upper surface of the substrate,
wherein the substrate is between the back coating film and the etch stop layer, and
wherein a portion of the back coating film contacts a portion of the etch stop layer at at least one of the first, second and third sides of the display panel.

14. The display panel of claim 8, further comprising:
a plurality of signal lines disposed on the substrate and configured to drive the plurality of subpixels,
wherein the fourth side of the display panel corresponds to ends of the plurality of signal lines.

15. The display panel of claim 8, wherein the first, second and third inclined edges of the first, second and third sides of the display panel are chemically etched edges, and
wherein the rounded edge of the fourth side of the display panel is a mechanically grinded edge.
